(19) United States
(12) Patent Application Publication
(10) Pub. No.: US 2025/0208232 A1
(43) Pub. Date: Jun. 26, 2025

(54) ORING FAULT DETECTION METHOD AND POWER SUPPLY SYSTEM

(71) Applicant: Delta Electronics (Shanghai) Co.,Ltd., Shanghai (CN)

(72) Inventors: Liangchao CHENG, Shanghai (CN); Jian ZHOU, Shanghai (CN); Youzhun CAI, Shanghai (CN); Changbing WANG, Shanghai (CN)

(21) Appl. No.: 18/963,810

(22) Filed: Nov. 29, 2024

(30) Foreign Application Priority Data
Dec. 25, 2023 (CN) 202311804202.7

(51) Int. Cl. G01R 31/52; G01R 19/165; H02J 1/10

(52) U.S. Cl. CPC G01R 31/52; G01R 19/165; H02J 1/108

(57) ABSTRACT

An ORING fault detection method and a power supply system are provided. The method may be applied to a power supply system including a plurality of power supply modules connected in parallel. The ORING fault detection method includes: starting primary units of the plurality of power supply modules in a time-sharing manner; starting secondary units of the plurality of power supply modules within a first delay; if a bus voltage at an output end of the power supply module within the first delay is within a first threshold range, initiating ORING detection of the power supply module, including: determining whether an ORING unit is in a healthy state by judging whether an output current of the power supply module has a negative current, or whether a voltage difference before and after the ORING unit of the power supply module is less than a preset value.

### CROSS-REFERENCE TO RELATED APPLICATIONS

This non-provisional application claims priority under 35 U.S.C. § 119 (a) on patent application No. 202311804202.7 filed in P.R. China on Dec. 25, 2023, the entire contents of which are hereby incorporated by reference.

Some references, if any, which may include patents, patent applications and various publications, may be cited and discussed in the description of this application. The citation and/or discussion of such references, if any, is provided merely to clarify the description of the present application and is not an admission that any such reference is “prior art” to the application described herein. All references listed, cited and/or discussed in this specification are incorporated herein by reference in their entireties and to the same extent as if each reference was individually incorporated by reference.

### BACKGROUND

### 1. Field of the Invention

The present disclosure relates to the field of power electronic technology, and particularly to an ORING fault detection method and a power supply system.

### 2. Related Art

In order to ensure safety and reliability of power supply, the power supply architecture of existing data center often uses an N+N multi-machine parallel redundancy system, while the redundant system in the centralized power supply system is especially important.

As for the centralized power supply system, it often includes a power supply module (which is also sometimes referred to as “a power supply unit (PSU)”) for powering loads (such as, servers), and a monitoring module (which is also sometimes referred to as “a shelf management controller (SMC)”) for monitoring states of all power supply modules and reporting to the system.

Since outputs of the power supply modules are connected in parallel together, a single point failure at an output end will cause an abnormality in the main output power, thereby seriously affecting the system's power supply and potentially leading to a system shutdown, and the function of an ORING unit (i.e., an anti-backflow unit) at the output side of the power supply module is to timely isolate the single point failure from an output bus. Therefore, the healthy state of the ORING unit within the power supply module becomes especially important, even directly affecting stability and reliability of the power supply system.

The ORING fault detection can effectively determine whether the ORING unit within the power supply module is operating normally, and prevent the inability to timely isolate fault from the output bus when a single power supply module fails due to an ORING fault. This prevention avoids a situation where the bus voltage is lowered or the system is shutdown.

The existing ORING fault detection method primarily determines whether the ORING unit has a fault by measuring voltage or current, but it still has the following issues:
(1) the existing ORING fault detection method cannot be independently executed by the power supply module itself and must be coordinated with the monitoring module (such as, SMC) of the system for detection. Therefore, if the monitoring module experiences a single-point failure, the ORING fault self-detection function cannot be realized;
(2) after all power supply modules have been running normally, the ORING fault detection can be started. If the ORING fault is present at the beginning of initial power on and a short-circuit fault occurs within the power source, it will cause the system's output voltage to drop or the system to shut down.

Therefore, how to detect ORING faulty state before the system starts up has become an urgent issue to be addressed in the industry.

### SUMMARY

An object of the disclosure is to provide an ORING fault detection method and a power supply system, which can effectively solve at least one deficiency in the prior art.

In order to achieve the object, the disclosure provides an ORING fault detection method, which is applied to a power supply system including a plurality of power supply modules connected in parallel, each power supply module including a primary unit, a secondary unit, an ORING unit and a control unit, the primary unit and the secondary unit of each power supply module being connected and the ORING unit located at an output side of the secondary unit, the control unit at least connected to the ORING unit, the method including:
starting the primary units of the plurality of power supply modules in a time-sharing manner;
starting the secondary units of the plurality of power supply modules within a first delay; and
as for each power supply module, if a bus voltage at an output end of the power supply module within the first delay is within a first threshold range, initiating ORING detection of the power supply module, including: determining whether the ORING unit is in a healthy state by judging whether an output current of the power supply module has a negative current, or whether a voltage difference before and after the ORING unit of the power supply module is less than a preset value.

In order to achieve the object, the disclosure further provides a power supply system, including: a plurality of power supply modules connected in parallel, each power supply module including a primary unit, a secondary unit, an ORING unit and a control unit, the primary unit and the secondary unit of each power supply module being connected and the ORING unit located at an output side of the secondary unit, the control unit at least connected to the ORING unit; wherein the control unit is configured to execute the ORING fault detection method as described above.

### BRIEF DESCRIPTION OF THE DRAWINGS

Exemplary embodiments are described in details with reference to the accompanying drawings, and the above and other features and advantages of the disclosure become more apparent.

FIG. 1 is a structural diagram of a power supply system according to the disclosure.

FIG. 2 is a schematic diagram of an interior structure of a power supply module according to the disclosure.

FIG. 3 is a flow diagram of an ORING fault detection method according to the disclosure.

FIG. 4 shows specific flows of a preferable ORING fault detection method according to the disclosure.

### DETAILED EMBODIMENTS

Now the exemplary embodiments are comprehensively described with reference to the accompanying drawings. However, the exemplary embodiments can be implemented in various forms, and shall not be understood to be limited to the described embodiments. On the contrary, these embodiments are provided to make the disclosure comprehensive and complete, and concept of the exemplary embodiments is fully conveyed to those skilled in the art. The same reference signs in the drawings represent the same or similar structure, so detailed descriptions are omitted.

When introducing the described or illustrated elements or components or the like, the words “one”, “first”, “the” and “at least one” represent one or more elements or components or the like. The terms “comprise”, “include” and “have” represent an open and including meaning, and refer to other elements or components or the like, except the listed elements or components or the like. Moreover, the terms “first”, “second” and the like in the claims are only used as signs, instead of limiting the number of the object. Furthermore, when one assembly is “connected” or “coupled” to another assembly, it may be directly connected or coupled to another assembly, or may have an intervention assembly.

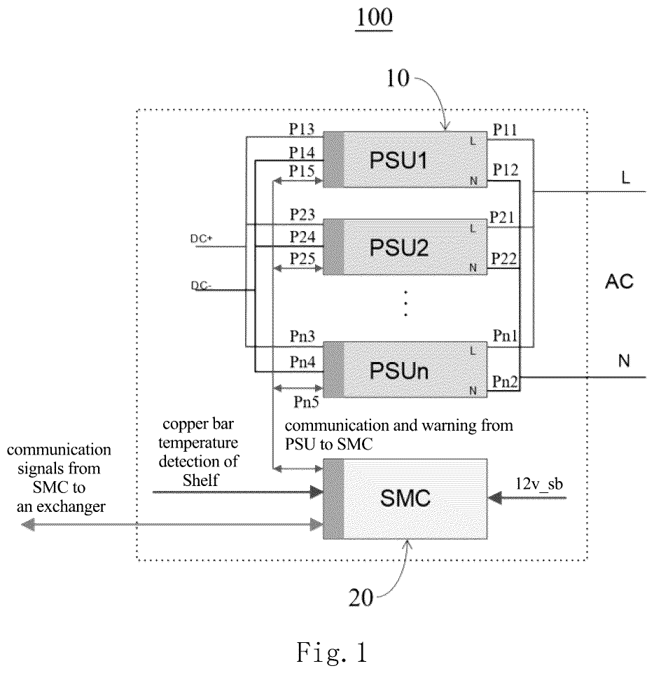

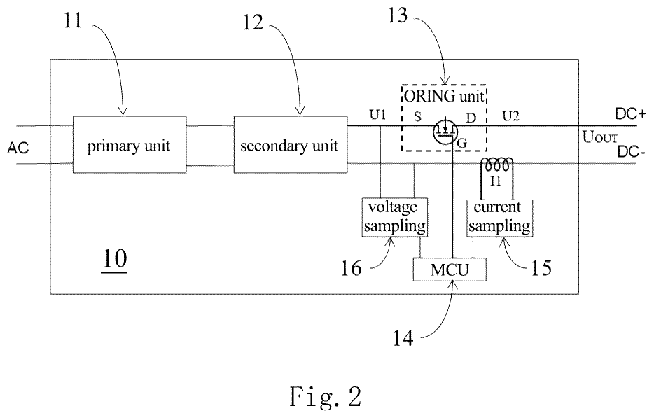

As shown in FIG. 1, it shows a structure of a power supply system 100 according to the disclosure, which may be configured for powering data centers including, but not limited to servers. The power supply system 100 of the disclosure may include a plurality of power supply modules 10 connected in parallel. For example, the embodiment of FIG. 1 shows n power supply modules 10 (which are PSU1, PSU2, . . . , PSUn, respectively) connected in parallel. Referring to FIG. 2, in the disclosure, each power supply module 10 includes a primary unit 11, a secondary unit 12, an ORING unit 13 and a control unit 14. The primary unit 11 and the secondary unit 12 of each power supply module 10 are electrically connected, and the ORING unit 13 is located at an output side of the secondary unit 12, for example, connected to a positive end of the output side of the secondary unit 12. The control unit 14 is at least connected to the ORING unit 13. In the disclosure, the control unit 14 is configured to execute an ORING fault detection method of the disclosure (for more specific method, hereinafter it will be described in details). In other embodiments, the power supply system 100 of the disclosure may further include a monitoring module 20 (which is also sometimes referred to as “a shelf management controller (SMC)”) for monitoring states of all power supply modules 10 and reporting to the system.

Please continue to refer to FIG. 1, in some embodiments of the disclosure, each power supply module 10 may preferably include a plurality of input terminals (e.g., P11, P12; P21, P22; . . . ; Pn1, Pn2) and a plurality of output terminals (e.g., P13, P14; P23, P24; . . . ; Pn3, Pn4), wherein first input terminals (e.g., P11, P21, . . . , and Pn1) in the plurality of input terminals of the n power supply modules 10, for example, are connected together to a live line L of an AC power source AC, and second input terminals (e.g., P12, P22, . . . , and Pn2) in the plurality of input terminals of the n power supply modules 10, for example, are connected together to a zero line N of the AC power source, first output terminals (e.g., P13, P23, . . . , and Pn3) in the plurality of output terminals of the n power supply modules 10, for example, are connected together to a positive end DC+ of the DC bus, and second output terminals (e.g., P14, P24, . . . , and Pn4) in the plurality of output terminals of the n power supply modules 10, for example, are connected together to a negative end DC− of the DC bus. However, it can be understood that the number of input terminals and output terminals of each power supply module 10 is not limited to the number shown in FIG. 1. In some other embodiments, each power supply module 10 may also include more numbers of terminals, for example, including but not limited to communication terminals P15, P25, . . . , and Pn5 in communication connection with the monitoring module 20 of the power supply system, which may achieve communication and warning from the respective power supply modules PSU1, PSU2, . . . , and PSUn to the monitoring module 20 (such as, SMC). In some other embodiments, the monitoring module 20 of the disclosure can receive, such as, temperature detection signal of a copper bar of a server shelf, and can also exchange communication signals from the monitoring module 20 (such as, SMC) to an exchanger, but the disclosure is also not limited thereto.

As shown in FIG. 2, referring to FIG. 1, in some embodiments of the disclosure, preferably, the ORING unit 13, for example, may be a MOS tube, which has a gate end G connected to the control unit 14, a source end S connected to the secondary unit 12, specifically, for example, connected to a positive end of the output side of the secondary unit 12, and a drain end D connected to a positive end DC+ of the DC bus. Preferably, the control unit 14, for example, may be a microprocessor (MCU), but the disclosure is not limited thereto. It can be understood that the control unit 14 of the disclosure may also be configured to execute other functions, and the disclosure is also not limited thereto. In the disclosure, a bus voltage U_{OUT} at output ends of the respective power supply modules 10, for example, is defined to be a voltage between the positive end DC+ of the DC bus and a negative end DC− of the DC bus. In some embodiments, preferably, a voltage (such as, a back-end voltage U2) at an output side of the ORING unit 13 may be used as the bus voltage U_{OUT} at the output end of the corresponding power supply module 10.

As shown in FIG. 2, in some embodiments of the disclosure, an output current I1 of the power supply module 10 can be acquired through a current sampling unit 15 connected to the output side of the secondary unit 12, and for example, the current sampling unit 15 in FIG. 2 is connected to a negative end of the output side of the secondary unit 12. However, it can be understood that in other embodiments, the current sampling unit 15 can also be connected to a positive end of the output side of the secondary unit 12.

As shown in FIG. 2, in some embodiments of the disclosure, a front-end voltage U1 of the ORING unit 13 of the corresponding power supply module 10 may be acquired through a first voltage sampling unit 16 connected to a front end of the ORING unit 13. A back-end voltage U2 of the ORING unit of the corresponding power supply module may be acquired through a second voltage sampling unit (not shown) connected to a back end of the ORING unit 13.

Accordingly, in the disclosure, the control units 14 of the respective power supply modules 10 may acquire and perform ORING detection of the corresponding power supply module according to the corresponding output current I1 of the respective power supply modules, or the front-end voltage U1 and the back-end voltage U2 of the corresponding ORING unit 13 of the respective power supply modules 10. Moreover, when detecting that the ORING unit is in a faulty state, the control unit 14 of the disclosure may also control the connection and disconnection of the ORING unit to reach the object of disconnection from the DC bus.

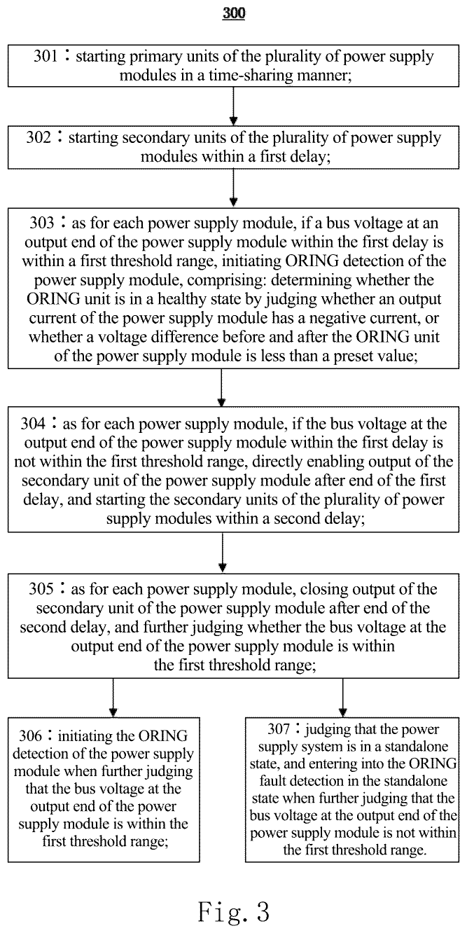

As shown in FIG. 3, it shows flows of an ORING fault detection method 300 according to the disclosure. The ORING fault detection method 300 of the disclosure may be applied to the power supply system 100 including a plurality of power supply modules 10 connected in parallel shown in FIGS. 1 to 2, and may include:
301: starting primary units of the plurality of power supply modules in a time-sharing manner;
302: starting secondary units of the plurality of power supply modules within a first delay. Through delayed starting of the respective power supply modules, the secondary unit of the power supply modules firstly started provides a voltage at a DC bus end, thereby facilitating judging a healthy state of the ORING unit of the power supply modules; and
303: as for each power supply module, if a bus voltage at an output end of the power supply module within the first delay is within a first threshold range, initiating ORING detection of the power supply module, including: determining whether the ORING unit is in a healthy state by judging whether an output current of the power supply module has a negative current, or whether a voltage difference before and after the ORING unit of the power supply module is less than a preset value.

In some embodiments of the disclosure, as shown in FIG. 3, the ORING fault detection method 300 of the disclosure further includes:
304: as for each power supply module, if the bus voltage at the output end of the power supply module is not within the first threshold range during the first delay, directly enabling the output of the secondary unit of the power supply module after the end of the first delay, and starting the secondary units of the plurality of power supply modules within a second delay;
305: as for each power supply module, closing the output of the secondary unit of the power supply module after the end of the second delay, and further judging whether the bus voltage at the output end of the power supply module is within the first threshold range;
306: initiating the ORING detection of the power supply module when further judging that the bus voltage at the output end of the power supply module is within the first threshold range; and
307: when further judging that the bus voltage at the output end of the power supply module is not within the first threshold range, judging that the power supply system is in a standalone state and entering into the ORING fault detection in the standalone state.

In some embodiments of the disclosure, starting within the first delay or starting within the second delay is performed according to the address bits of the plurality of power supply modules.

In some embodiments of the disclosure, the power supply system has a table reflecting a correspondence relation between the address bits of the plurality of power supply modules and delay times (e.g., as shown in Table 1), and when starting within the first delay or starting within the second delay, the respective power supply modules acquire the corresponding delay times of the respective power supply modules for delayed starting by the way of inquiring the table.

TABLE 1

| Address Bit (the corresponding power | |
|---|---|
| supply module) | Delay Time |
| 0000 (PSU1) | 8 s |
| 0001 (PSU2) | 16 s |
| 0010 (PSU3) | 24 s |
| 0011 (PSU4) | 32 s |
| . . . | . . . |

Preferably, as shown in Table 1, it only illustratively shows power supply modules PSU1, PSU2, PSU3, PSU4, . . . having address bits 0000, 0001, 0010, 0011, . . . , and corresponding delay times 8 s, 16 s, 24 s, 32 s, . . . . However, it can be understood that the correspondence relation between the address bits and the delay times shown in Table 1 does not use as limits to the disclosure.

In some embodiments of the disclosure, preferably, the corresponding first delay time or second delay time of the respective power supply modules 10, for example, are both less than 60 s. Preferably, a time interval of starting the primary units 11 of the plurality of power supply modules 10 in a time-sharing manner, for example, is not more than 8 s. Preferably, the first threshold range is set within a rated range, and may be flexibly set according to actual requirements, and a first threshold, for example, is within different rated ranges such as 12V, 48V or 54V. However, it can be understood that the disclosure is not limited thereto.

In some embodiments of the disclosure, as for each power supply module, the ORING detection of the power supply module includes: determining a healthy state of the ORING unit by judging whether the output current of the power supply module has the negative current, or whether the voltage difference before and after the ORING unit is less than the preset value; if the output current of the power supply module has the negative current, or the voltage difference before and after the ORING unit is less than the preset value, determining that the ORING unit is in a faulty state; if the output current of the power supply module does not have the negative current, and the voltage difference before and after the ORING unit is not less than the preset value, determining that the ORING unit is in a normal state. Taking the power supply module of FIG. 2 for example, the healthy state of the ORING unit 13 can be determined by judging whether the output current I1 of the power supply module 10 has the negative current, or the voltage difference ΔU=U2−U1 before and after the ORING unit 13. For example, when judging that the output current I1 of the power supply module 10 has the negative current, or ΔU<3V, it can be considered that the ORING unit 13 is in a faulty state; when judging that the output current I1 of the power supply module 10 does not have the negative current and ΔU≥3V, it can be considered that the ORING unit 13 is in a normal state. In some embodiments of the disclosure, when the voltage difference ΔU before and after the ORING unit 13 is compared to the preset value, comparison is made using an absolute value of the voltage difference ΔU before and after the ORING unit 13.

Preferably, in some embodiments of the disclosure, when determining that the ORING unit 13 is in a faulty state, the control unit 14 disables the output of the secondary unit 12 of the corresponding power supply module and controls disconnection of the ORING unit 13.

In some embodiments of the disclosure, preferably, the “the ORING fault detection in the standalone state”, for example, may be executed according to actual situations: disabling the output of the secondary unit of the power supply module, further judging whether the bus voltage at the output end of the power supply module is within the first threshold range, and when further judging that the bus voltage at the output end of the power supply module is within the first threshold range, initiating the ORING detection of the power supply module; when further judging that the bus voltage at the output end of the power supply module is not within the first threshold range, judging that the power supply system is still in the standalone state, and further entering into the ORING fault detection in the standalone state; or directly enabling the output of the secondary unit of the power supply module, and not judging fault of the ORING unit.

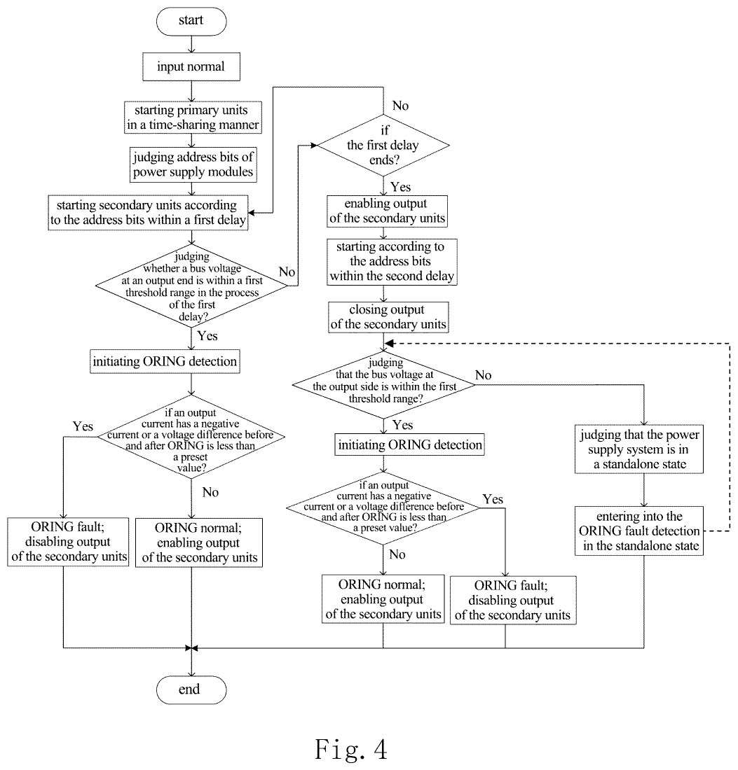

In order to achieve judging of the healthy state of the ORING unit before starting, and ORING detection logic decoupled from the monitoring module (such as, SMC), the disclosure provides a specific logic block diagram shown in FIG. 4:
(1) when input is normal (e.g., input of the AC power source of the power supply system is normal), starting the primary units of the respective power supply modules of the power supply system in a time-sharing manner;
(2) judging address bits of the power supply modules, and starting the secondary units of the power supply modules according to the address bits within the first delay. Through delayed starting of the power supply modules, the secondary unit of the power supply module firstly started provides a voltage at a DC bus end, thereby facilitating judging the healthy state of the ORING units of the respective power supply modules.
(3) judging whether the bus voltage at the output end of the power supply module is within the first threshold range in the process of the first delay? If judging that the bus voltage at the output end is within the first threshold range in the first delay, initiating ORING detection, i.e., determining a healthy state of ORING by judging whether the output current has a negative current or the voltage difference before and after ORING is less than the preset value; if the output current has the negative current, or the voltage difference before and after ORING is less than the preset value, determining the ORING fault, and disabling output of the secondary unit of the power supply module; if the output current does not have the negative current, and the voltage difference before and after ORING is not less than the preset value, determining that ORING is normal, and enabling output of the secondary unit of the power supply module.
(4) if judging that the bus voltage at the output end of the power supply module is not within the first threshold range in the first delay, directly enabling the output of the secondary unit after the end of the first delay, starting according to the address bits within the second delay, closing the output of the secondary after the end of the second delay, and further judging whether the bus voltage at the output end of the power supply module is within the first threshold range;
(5) if the bus voltage at the output end is within the first threshold range, initiating the ORING detection as that in (3);
(6) if the bus voltage at the output end is not within the first threshold range, judging that the power supply system is in a standalone state, and entering into the ORING fault detection in the standalone state: for example, disabling the output of the secondary unit, and judging the ORING detection cyclically, or directly enabling output of the secondary unit, and not judging fault of the ORING.

In conclusion, the disclosure provides a way of detecting fault of the ORING in the process of starting in a time-sharing manner, and may detect the ORING faulty state before running of the system (i.e., before powering on), which can avoid the system from bringing the faulty machine into system running, and reduce a risk of overall shutdown after the system is powered on. Meanwhile, the power supply modules of the disclosure may independently detect the ORING state to be completely decoupled from a system end, and under conditions of ensuring no system or communication failure with the system, still can complete ORING self-detection, so as to reduce a risk of shutdown of the system to the lowest. In other words, the disclosure can also perform ORING self-detection in the absence of the monitoring module (such as, SMC) of the system.

The exemplary embodiments of the disclosure are illustrated and described in details. It shall be understood that the disclosure is not limited to the disclosed embodiments. In contrast, the disclosure intends to cover various modifications and equivalent arrangements included in spirit and scope of the appended claims.

What is claimed is:

1. An ORING fault detection method, which is applied to a power supply system comprising a plurality of power supply modules connected in parallel, each power supply module comprising a primary unit, a secondary unit, an ORING unit and a control unit, the primary unit and the secondary unit of each power supply module being connected and the ORING unit located at an output side of the secondary unit, the control unit at least connected to the ORING unit, the method comprising:
starting the primary units of the plurality of power supply modules in a time-sharing manner;
starting the secondary units of the plurality of power supply modules within a first delay; and
as for each power supply module, if a bus voltage at an output end of the power supply module within the first delay is within a first threshold range, initiating ORING detection of the power supply module, comprising: determining whether the ORING unit is in a healthy state by judging whether an output current of the power supply module has a negative current, or whether a voltage difference before and after the ORING unit of the power supply module is less than a preset value.

2. The ORING fault detection method according to claim 1, further comprising: if the bus voltage at the output end of the power supply module is not within the first threshold range during the first delay, directly enabling the output of the secondary unit of the power supply module after the end of the first delay, and starting the secondary units of the plurality of power supply modules within a second delay.

3. The ORING fault detection method according to claim 2, further comprising: closing the output of the secondary unit of the power supply module after the end of the second delay, and further judging whether the bus voltage at the output end of the power supply module is within the first threshold range;
initiating the ORING detection of the power supply module when further judging that the bus voltage at the output end of the power supply module is within the first threshold range; and
when further judging that the bus voltage at the output end of the power supply module is not within the first threshold range, judging that the power supply system is in a standalone state and entering into the ORING fault detection in the standalone state.

4. The ORING fault detection method according to claim 2, wherein starting within the first delay or starting within the second delay is performed according to the address bits of the plurality of power supply modules.

5. The ORING fault detection method according to claim 4, wherein the power supply system has a table reflecting a correspondence relation between the address bits of the plurality of power supply modules and delay times, and when starting within the first delay or starting within the second delay, the respective power supply modules acquire the corresponding delay times of the respective power supply modules for delayed starting by the way of inquiring the table.

6. The ORING fault detection method according to claim 1, wherein as for each power supply module, the ORING detection of the power supply module further comprises:
if the output current of the power supply module has the negative current, or the voltage difference before and after the ORING unit is less than the preset value, determining that the ORING unit is in a faulty state;
if the output current of the power supply module does not have the negative current, and the voltage difference before and after the ORING unit is not less than the preset value, determining that the ORING unit is in a normal state.

7. The ORING fault detection method according to claim 6, further comprising:
when determining that the ORING unit is in the faulty state, the control unit disabling the output of the secondary unit of the power supply module and controlling disconnection of the ORING unit.

8. The ORING fault detection method according to claim 1, further comprising:
acquiring the output current of the power supply module through a current sampling unit connected to the output end of the secondary unit of the power supply module;
acquiring a front-end voltage of the ORING unit of the power supply module through a first voltage sampling unit connected to a front end of the ORING unit of the power supply module; and
acquiring a back-end voltage of the ORING unit of the power supply module through a second voltage sampling unit connected to a back end of the ORING unit of the power supply module;
wherein the control units of the respective power supply modules acquire and perform ORING detection of the power supply module according to the corresponding output current of the respective power supply modules, or the front-end voltage and the back-end voltage of the corresponding ORING unit of the respective power supply modules.

9. The ORING fault detection method according to claim 3, wherein the ORING fault detection in the standalone state comprises:
disabling the output of the secondary unit of the power supply module, further judging whether the bus voltage at the output end of the power supply module is within the first threshold range, and when further judging that the bus voltage at the output end of the power supply module is within the first threshold range, initiating the ORING detection of the power supply module; when further judging that the bus voltage at the output end of the power supply module is not within the first threshold range, judging that the power supply system is still in the standalone state, and further entering into the ORING fault detection in the standalone state; or
directly enabling the output of the secondary unit of the power supply module, and not judging fault of the ORING unit.

10. The ORING fault detection method according to claim 4, wherein,
the corresponding first delay time or second delay time of the respective power supply modules are both less than 60 s;
a time interval of starting the primary units of the plurality of power supply modules in a time-sharing manner is not more than 8 s.

11. The ORING fault detection method according to claim 1, wherein the bus voltage at the output end of the power supply module is a voltage at an output side of the ORING unit.

12. A power supply system, comprising:
a plurality of power supply modules connected in parallel, each power supply module comprising a primary unit, a secondary unit, an ORING unit and a control unit, the primary unit and the secondary unit of each power supply module being connected and the ORING unit located at an output side of the secondary unit, the control unit at least connected to the ORING unit;
wherein the control unit is configured to execute the ORING fault detection method according to claim 1.

13. The power supply system according to claim 12, wherein,
each power supply module further comprises a plurality of input terminals and a plurality of output terminals;
a first input terminal in the plurality of input terminals of each power supply module is connected to a live line of an AC power source, and a second input terminal in the plurality of input terminals of each power supply module is connected to a zero line of the AC power source;
a first output terminal in the plurality of output terminals of each power supply module is connected to a positive end of the DC bus, and a second output terminal in the plurality of output terminals of each power supply module is connected to a negative end of the DC bus.

14. The power supply system according to claim 13, wherein when the control unit executes the following ORING fault detection method:
starting the primary units of the plurality of power supply modules in a time-sharing manner;
starting the secondary units of the plurality of power supply modules within a first delay; and
as for each power supply module, if a bus voltage at an output end of the power supply module within the first delay is within a first threshold range, initiating ORING detection of the power supply module, comprising: determining whether the ORING unit is in a healthy state by judging whether an output current of the power supply module has a negative current, or whether a voltage difference before and after the ORING unit of the power supply module is less than a preset value,
a current sampling unit is connected to a positive end of the output side or a negative end of the output side of the secondary unit of the power supply module for acquiring the output current of the power supply module.

15. The power supply system according to claim 13, wherein the ORING unit is a MOS tube, a gate end of the MOS tube is connected to the control unit, a source end of the MOS tube is connected to the secondary unit, and a drain end of the MOS tube is connected to the positive end of the DC bus.
